(19) United States
(12) Patent Application Publication
(10) Pub. No.: US 2021/0013124 A1
(43) Pub. Date: Jan. 14, 2021

(54) HEAT DISSIPATING STRUCTURE FOR ELECTRONIC UNITS AND DISPLAY DEVICE COMPRISING SAME

(71) Applicant: NIPPON SEIKI CO., LTD., Niigata (JP)

(72) Inventor: Mitsuru IKENO, Niigata (JP)

(21) Appl. No.: 17/040,830

(22) PCT Filed: Apr. 12, 2019
(86) PCT No.: PCT/JP2019/015956

§ 371 Date: Sep. 23, 2020

(30) Foreign Application Priority Data
Apr. 19, 2018 (JP) 2018-080570

(51) Int. Cl. H01L 23/40; G02F 1/1333; H01L 25/18; B60K 35/00

(52) U.S. Cl. CPC H01L 23/4006; G02F 1/133308; H01L 25/18; B60K 35/00; H01L 2023/4068; B60K 2370/169; G02F 2001/133314; B60K 2370/40; B60K 2370/152; B60K 2370/167; H01L 2023/4087

(57) ABSTRACT

Provided are a heat dissipating structure with which stress on an electronic unit that generates heat can be reduced, and a display device comprising the same. The heat dissipating structure comprises: at least two electronic units, e.g. electronic units, that are provided on a circuit hoard, differ from one another in height from the circuit board, and generate heat; a dissipating member for dissipating heat generated from the electronic units; and heat conducting members that are sandwiched between the electronic units and the heat dissipating member so as to conduct heat, wherein the heat conducting members provided between the electronic units and the heat dissipating member have the same thickness.

### TECHNICAL FIELD

The present disclosure relates to a heat dissipating structure of an electronic unit generating heat and a display device including the heat dissipating structure.

### BACKGROUND ART

Conventionally, in an example of such a type of structure, a structure described in Patent Document 1 below is known. Patent Document 1 discloses the structure including a heat sink facing an electronic unit (heat-generating element) generating heat, and a blower unit including blower means for blowing air to the heat sink. Between the electronic unit and the heat sink, there is provided a constant gap which is filled with a gel-like heat conductive grease having high viscosity, a heat conductive sheet having excellent elasticity, or the like.

### PRIOR ART DOCUMENT

### Patent Document

Patent Document 1: Japanese Unexamined Patent Application Publication No. 2009-130258

### SUMMARY OF THE INVENTION

### Problems to be Solved by the Invention

However, if the structure includes a plurality of electronic units having height different from each other, the heat conductive sheet and the heat sink are shared among the plurality of electronic units, and an abutment surface of the heat sink against the heat conductive sheet is a flat surface, the compression amounts in the heat conductive sheet are different depending on the heights of the plurality of electronic units, and thus, if a distance between one of the electronic units and the heat sink is short, there is a problem in that an excessive load is applied to the electronic unit and the electronic unit may be damaged.

Therefore, the present disclosure has been made in view of the above problems, and an object thereof is to provide a heat dissipating structure capable of reducing stress on an electronic unit generating heat, and a display device including the heat dissipating structure.

### Solution to Problem

The present disclosure includes a circuit board 4, at least two or more electronic units 43, 44, and 45 generating heat, the electronic units 43, 44, and 45 being arranged on the circuit board 4 and having different heights from the circuit board 4 from each other, a heat dissipating member 8 configured to dissipate heat generated by the electronic units 43, 44, and 45, and heat transfer members 6 arranged closely between the electronic units 43, 44, and 45 and the heat dissipating member 8 and configured to conduct the heat. The heat transfer members 6 arranged between the electronic units 43, 44, and 45 and the heat dissipating member 8 have the same thickness.

### Effect of the Invention

According to the present disclosure, it is possible to provide a heat dissipating structure capable of achieving the intended object and reducing stress on an electronic unit generating heat, and a display device including the heat dissipating structure.

### BRIEF DESCRIPTION OF THE DRAWINGS

FIG. 1 is a front view of a display device illustrating an embodiment of the present disclosure.

FIG. 2 is a cross-sectional view taken along a line A-A in FIG. 1.

FIG. 3 is an enlarged view of a major part of FIG. 1.

### MODE FOR CARRYING OUT THE INVENTION

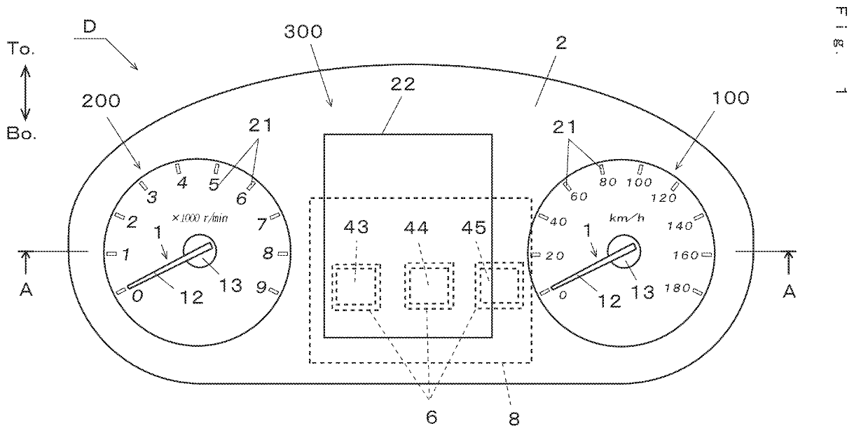

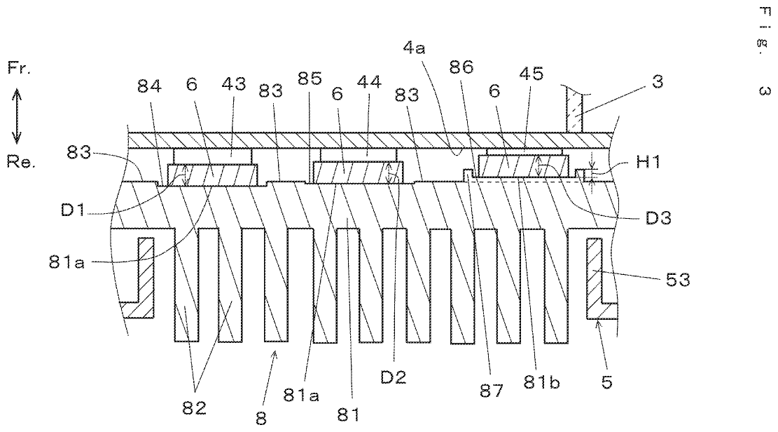

A case where a display device according to the present disclosure is applied to a vehicular instrument mounted on a vehicle will be described below for an example with reference to FIGS. 1 to 3.

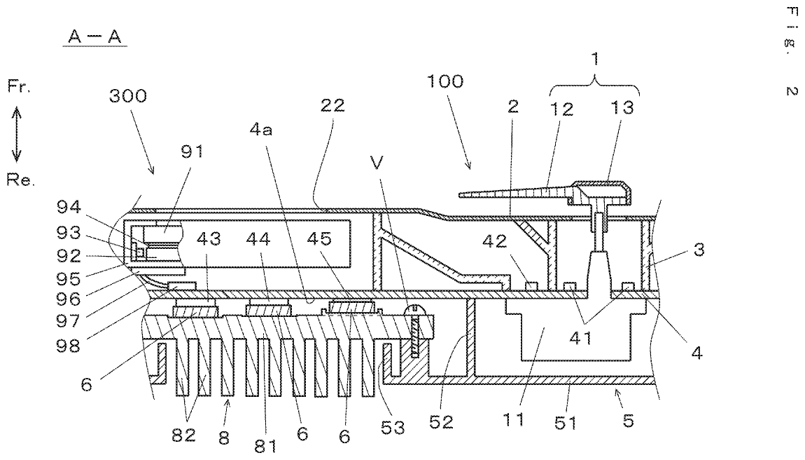

In the following description, a “front side” refers to a near side in FIG. 1 and an upper side (side of a dial plate 2) in FIG. 2, and the “front side” is visible to a viewer (driver). A “back (rear) side” refers to a far side in FIG. 1 and a lower side in FIG. 2 (side of a lower case 5).

In FIG. 1, a vehicular instrument D includes a pointer-type speedometer (display indicator) 100 configured to display a vehicle speed (vehicle information) and the like, a pointer-type tachometer (display indicator) 200 configured to display an engine RPM (vehicle information), and a digital meter (display indicator) 300 configured to display various types of vehicle information such as a traveling distance, fuel consumption, and time. The digital meter 300 is located between the speedometer 100 and the tachometer 200, and the speedometer 100, the tachometer 200, and the digital meter 300 are arranged in a parallel manner.

As illustrated in FIGS. 1 and 2, the speedometer 100 and the tachometer 200 mainly include a pointer 1, a drive main body 11 including an instrument movement that operates the pointer 1, a circuit board 4 to which the drive main body 11 is conductively mounted, and the dial plate 2 being provided between the pointer 1 and the circuit board 4 and including an indication portion 21 such as scale marks or numbers pointed by the pointer 1. A plurality of light emitting elements (light emitting diodes: LEDs) 41 and 42 corresponding to the pointer 1 and the dial plate 2 are mounted on the circuit board 4 provided behind the dial plate 2.

The pointer 1 includes an indicator portion 12 formed of a translucent resin and a pointer cap 13 formed of a non-transparent resin. The pointer 1 is connected to a rotation shaft of the drive main body 11, and the indicator portion 12 points to the indication portion 21. The drive main body 11 includes a movable magnet-type drive main body, a stepping motor, and the like, and is mounted behind the circuit board 4. A pivot shaft of the drive main body 11 protrudes forward.

The dial plate 2 includes the indication portion 21 printed with ink on front and back sides of a thin plate-shaped base material formed of a translucent synthetic resin, for example.

In this case, the pointer 1 is formed of a light-transmitting material capable of emitting light if receiving irradiation light obtained when the light emitting element 41 lights up. Further, the indication portion 21 of the dial plate 2 is formed of a light-transmitting material so that if the light emitting element 42 lights up, the indication portion 21 receives the irradiation light of the light emitting element 42 and emits light.

It is noted that, a substantially rectangular opening window 22 is formed at a location of the dial plate 2 corresponding to the digital meter 300 to expose a required portion of the digital meter 300 (specifically, a display area of a display element 91 described later included in the digital meter 300).

The circuit board 4 is formed of, for example, a hard wiring board having a wiring pattern on a glass epoxy base material, and electronic units are (arranged to be) conductively connected to the wiring pattern. Examples of the electronic units include the drive main body 11, the light emitting elements 41 and 42, at least two, that is, a plurality of integrated circuit (IC) chips (a first IC chip, a second IC chip, and a third IC chip) 43, 44, and 45, a resistor, and a capacitor. These electronic units generate heat if electricity flows through the electronic units.

The first IC chip 43 is a thin plate-shaped and rectangular microchip and is mounted behind the circuit board 4. Further, the first IC chip 43 functions as a graphics display controller (GDC) (drawing control controller) and causes the digital meter 300 to display vehicle information, based on a control signal output from the second IC chip 44.

The second IC chip 44 is a thin plate-shaped and rectangular microchip and is mounted behind the circuit board 4. Further, the second IC chip 44 functions as a microcomputer, includes a central processing unit (CPU), a read only memory (ROM), a random access memory (RAM), and the like, and executes a predetermined arithmetic process according to a program written in the ROM, for example.

Further, the second IC chip 44 acquires a vehicle speed, an engine RPM, various types of vehicle information, navigation information, and the like from an electronic control unit (ECU) of the vehicle via various types of sensors or the like, and drives/controls the drive main body 11, the light emitting element 41, the light emitting element 42, and the digital meter 300, based on the acquired information.

The third IC chip 45 is a thin plate-shaped and rectangular microchip and is mounted behind the circuit board 4. Further, the third IC chip 45 is a synchronous dynamic random access memory (SDRAM) belonging to the Double Data Rate (DDR) standard having a high bit rate for communication, and is used as a temporary storage of a large amount of image data from the first IC chip 43.

The IC chips (the first IC chip, the second IC chip, and the third IC chip) 44, 43, and 45 are units each having different height (thicknesses) in a normal direction of the circuit board 4. In the present disclosure, the first IC chip 43 has the greatest height, the second IC chip 44 has the second-greatest height, and the third IC chip 45 has the lowest height. Each of the IC chips 43, 44, and 45 is a unit having a height of about 1 mm to 2 mm.

Further, each of the IC chips 43, 44, and 45 is mounted at a position facing a main body portion 81 of a heat dissipating member 8 described later behind the circuit board 4. Needless to say, the IC chips 43, 44, and 45 are mounted on the same flat surface 4a of the circuit board 4.

A middle case 3 formed of, for example, a white synthetic resin is provided in front of the circuit board 4, and a plurality of illumination chambers that accommodate the light emitting elements 41 and 42 and guide light of the light emitting elements 41 and 42 toward the pointer 1 and the dial plate 2 are formed in the middle case 3. It is noted that the middle case 3 has a function as a holding body that holds the dial plate 2 and the digital meter 300 (see FIG. 2).

A facing member (not illustrated) is arranged in front of the middle case 3, and the facing member exposes a visible area of the speedometer 100 and the tachometer 200 (that is, the pointer 1 and the indication portion 21) and the opening window 22. Further, a transparent or semi-transparent see-through panel (not illustrated) formed in a curved shape, for example, is arranged in front of the facing member.

The lower case 5 accommodates the dial plate 2, the middle case 3, the circuit board 4, the digital meter 300, the heat dissipating member 8, and the like and is formed of, for example, a white light-shielding synthetic resin. The lower case 5 is formed substantially in a box shape having a bottom, and has a configuration in which a substantially flat plate-shaped base portion 51 behind the circuit board 4 to be separated from the circuit board 4 and a plurality of abutting portions 52 holding the circuit board 4 are integrally formed.

As illustrated in FIG. 2, the digital meter 300 includes the display element 91, a source line drive circuit (not illustrated) configured to drive a source line (signal line) of the display element 91, a gate line drive circuit (not illustrated) configured to drive a gate line (scanning line) of the display element 91, a light-guide body 92, a light source 93, and an optical sheet 94 including, for example, a plurality of diffusion sheets or prism sheets. The digital meter 300 includes a frame body 95 that is formed of an electroconductive material and forms an outer case of the digital meter 300 configured to accommodate and hold the display element 91, the light-guide body 92, the light source 93, and the optical sheet 94. The digital meter 300 includes a printed circuit board 96 on which a timing controller and the like (not illustrated) configured to generate various types of timing signals for controlling a timing of the source line drive circuit and the gate line drive circuit is mounted.

The display element 91 is formed of, for example, a thin film transistor (TFT) type liquid crystal display (LCD) element including a plurality of pixels and displays vehicle information (predetermined information) such as a traveling distance and fuel consumption, based on a detection signal from various types of sensors mounted in the vehicle.

The light-guide body 92 is formed of a substantially flat plate-shaped translucent synthetic resin. The light source 93 includes an LED accordingly emitting a color. The frame body 95 is formed of an electroconductive material. The printed circuit board 96 is fixed to a back surface of the frame body 95 by using appropriate fixing means, and is connected to the circuit board 4 via a flexible wiring board 97 and a connector 98.

Further, the heat dissipating member 8 being a heat sink for dissipating heat generated by each of the IC chips 43, 44, and 45 is arranged behind the circuit board 4 to cover each of the IC chips 43, 44, and 45. The heat dissipating member 8 is formed of a metal material such as aluminum having a high thermal conductivity, and the entire surface of the heat dissipating member 8 is subjected to an anodic oxide coating treatment as a measure for preventing oxidation of the surface and is covered with an anodic oxide film. Further, the heat dissipating member 8 includes the main body portion 81 formed in a plate-like and substantially rectangular shape, and a large number of heat dissipating fin portions 82 capable of contacting outside air (atmosphere) outside the lower case 5, on a back side of the main body portion 81.

The heat dissipating fin portions 82 are formed by aligning a plurality of protruding pieces from an opening portion 53 provided in the lower case 5 to the outside. It is noted that the heat dissipating member 8 is fixed to the lower case 5 by using appropriate fixing means. For example, in the present disclosure, the heat dissipating member 8 is fixed to the base portion 51 of the lower case 5 from the side of the circuit board 4 by using screws V or the like at four corners of the main body portion 81.

A heat conducting member (heat transfer member) 6 having an adhesive surface is arranged (placed) between each of the IC chips 43, 44, and 45 and the main body portion 81 so that the heat conducting member 6 closely attaches to each of the IC chips 43, 44, and 45 and the main body portion 81. The heat conducting member 6 is formed of an elastic body having good thermal conductivity, and is called a thermal interface material (TIM) or a heat conductive sheet. With such a heat dissipating structure, the heat generated by each of the IC chips 43, 44, and 45 is conducted to the main body portion 81 of the heat dissipating member 8 via the heat conducting members 6 and dissipated by the heat dissipating fin portions 82, and thus, the temperature can be efficiently reduced.

Each of the heat conducting members 6 is arranged between each of the IC chips 43, 44, and 45 and the main body portion 81, and all three of the heat conducting members 6 are the same units. Thus, the heat conducting members 6 are naturally each formed to have the same thickness. It is noted that, after being attached to the heat dissipating member 8, the heat conducting members 6 abut against each of the IC chips 43, 44, and 45.

The main body portion 81 of the heat dissipating member 8 includes a general surface 83 formed in parallel to the flat surface 4a of the circuit board 4. Further, the main body portion 81 includes a first abutment surface 84 that abuts against the heat conducting member 6 abutting against the first IC chip 43, a second abutment surface 85 that abuts against the heat conducting member 6 abutting against the second IC chip 44, and a third abutment surface 86 that abuts against the heat conducting member 6 abutting against the third IC chip 45.

The difference between the first abutment surface 84 and the second abutment surface 85 in a height direction (normal direction of the flat surface 4a of the circuit board 4) is the same as the difference between the first IC chip 43 and the second IC chip 44 in the height direction. Further, the difference between the second abutment surface 85 and the third abutment surface 86 in the height direction is the same as the difference between the second IC chip 44 and the third IC chip 45 in the height direction.

The first abutment surface 84 is formed on a bottom surface of a concave portion 81a recessed in a direction opposite to the circuit board 4 with respect to the general surface 83 being an outer peripheral surface of the first abutment surface 84. The second abutment surface 85 is formed on a bottom surface of a concave portion 81a recessed in a direction opposite to the circuit board 4 with respect to the general surface 83 being an outer peripheral surface of the second abutment surface 85. The third abutment surface 86 is formed on a top surface of a protruding portion 81b protruding in a direction of the circuit board 4 with respect to the general surface 83 being an outer peripheral surface of the third abutment surface 86.

It is noted that an anodic oxide film having thermal conductivity lower than a base material is removed from each of the abutment surfaces (the first abutment surface, the second abutment surface, and the third abutment surface) 84, 85, and 86. That is, there is no anodic oxide film between the heat conducting members 6 and each of the abutment surfaces 84, 85, and 86.

A distance D1 between the first IC chip 43 and the first abutment surface 84 facing the first IC chip 43, a distance D2 between the second IC chip 44 and the second abutment surface 85 facing the second IC chip 44, and a distance D3 between the third IC chip 45 and the third abutment surface 86 facing the third IC chip 45 are set to the same distance. It is noted that the distances D1, D2, and D3 are set to about 70% to 80% of the thickness of the heat conducting members 6. That is, the heat conducting members 6 are placed in a state of being compressed by about 20% to 30% at the distances D1, D2, and D3.

The distances D1, D2, and D3 are set to about 3 mm.

The third abutment surface 86 includes a positioning portion 87 that positions the heat conducting member 6 and is formed in a convex shape from the general surface 83 toward the circuit board 4 to surround an outer periphery of the third abutment surface 86. A protrusion amount H1 of the positioning portion 87 from the third abutment surface 86 is formed to be smaller than the distance D3.

With such a configuration, the gaps between the IC chips 43, 44, and 45 and the abutment surfaces 84, 85, and 86 can be made constant at the distances D1, D2, and D3, and thus, compared to a case where different gaps are set and the heat conducting members 6 have different thickness, it is possible to reduce the manufacturing cost and provide a low-cost display device.

Further, with such a configuration, the compression amount of each of the heat conducting members 6 can be made constant, and thus, it is possible to prevent different loads from applying to each of the IC chips 43, 44, and 45 due to variations in the compression amount of the heat conducting members 6, and to prevent the occurrence of a load to damage the IC chips 43, 44, and 45 to provide a highly safe display device.

With such a configuration, the heat conducting members 6 formed of an elastic body are arranged in the gaps having a length of about 3 mm between each of the IC chips 43, 44, and 45 and the heat dissipating member 8, and thus, it is possible to eliminate variations in dimensions of each unit, variations in assembly, and rattling and the like between units due to a vibration of the vehicle. Therefore, it is possible to prevent a load from acting upon the IC chips 43, 44, and 45 and provide a highly safe display device.

With such a configuration, the positioning portion 87 can be used as a guide for attaching the heat conducting member 6, and thus, it is possible to provide a display device that can be assembled easily and quickly.

Further, the concave portion 81a can also be used as a guide for attaching the heat conducting member 6, and thus, it is possible to provide a display device that can be assembled easily and quickly.

It is noted that the display device according to the present disclosure is described by employing the configuration in the above-described embodiment as an example, but the present disclosure is not limited thereto, and it is needless to say that even in another configuration, the present disclosure may be variously modified and a design thereof may be changed without departing from the spirit of the present disclosure.

In the case of the present embodiment, an end portion of the heat dissipating fin portion 82 is substantially on the same plane as the bottom surface of the base portion 51 of the lower case 5. However, the end portion of the heat dissipating fin portion 82 may protrude from the bottom surface of the base portion 51, for example.

### DESCRIPTION OF REFERENCE NUMERALS

4 Circuit board
43 First IC chip (electronic unit)
44 Second IC chip (electronic unit)
45 Third IC chip (electronic unit)
6 Heat conducting member (heat transfer member)
8 Heat dissipating member
81a Concave portion
81b Protruding portion
84 First abutment surface (abutment surface)
85 Second abutment surface (abutment surface)
86 Third abutment surface (abutment surface)
87 Positioning portion
D1 Distance between first IC chip 43 and first abutment surface 84 facing first IC chip 43
D2 Distance between second IC chip 44 and second abutment surface 85 facing second IC chip 44
D3 Distance between third IC chip 45 and third abutment surface 86 facing third IC chip 45
H1 Protrusion amount of the positioning portion from the abutment surface
100 Speedometer (display indicator)
200 Tachometer (display indicator)
300 Digital meter (display indicator)

1. A heat dissipating structure comprising:
a circuit board;
at least two or more electronic units generating heat, the electronic units being arranged on the circuit board and having different heights from the circuit board from each other;
a heat dissipating member configured to dissipate heat generated by the electronic units; and
heat transfer members arranged closely between the electronic units and the heat dissipating member and configured to conduct the heat, wherein
the heat transfer members arranged between the electronic units and the heat dissipating member have the same thickness.

2. The heat dissipating structure according to claim 1, wherein an abutment surface of the heat dissipating member abutting against the heat transfer members is formed into a concave portion.

3. The heat dissipating structure according to claim 1, wherein an abutment surface of the heat dissipating member abutting against the heat transfer members is formed into a protruding portion.

4. The heat dissipating structure according to claim 3, comprising a positioning portion formed to protrude from the abutment surface on an outer periphery of the abutment surface.

5. The heat dissipating structure according to claim 1, wherein a surface of the heat dissipating member is covered with an anodic oxide film, and an abutment surface of the heat dissipating member abutting against the heat transfer members is not covered with the anodic oxide film.

6. The heat dissipating structure according to claim 1, wherein distances between the electronic units and the heat dissipating member are the same.

7. A display device comprising a display indicator configured to display vehicle information in the heat dissipating structure according to claim 1.
